(19) United States
(12) Patent Application Publication
(10) Pub. No.: US 2026/0130191 A1
(43) Pub. Date: May 7, 2026

(54) SEMICONDUCTOR PACKAGE

(71) Applicant: Samsung Electronics Co., Ltd., Suwon-si (KR)

(72) Inventors: Joo Hee JANG, Suwon-si (KR); Ho-Jin LEE, Suwon-si (KR); Jun Hong MIN, Suwon-si (KR); Seong Min SON, Suwon-si (KR); Seung Don LEE, Suwon-si (KR); Hyun Jin LEE, Suwon-si (KR); Dong-Chan LIM, Suwon-si (KR)

(21) Appl. No.: 19/287,951

(22) Filed: Aug. 1, 2025

(30) Foreign Application Priority Data
Nov. 5, 2024 (KR) 10-2024-0155470

(51) Int. Cl. H01L 23/00; H01L 23/31; H01L 23/48; H01L 25/065; H01L 25/16

(52) U.S. Cl. CPC H10W 20/20; H10W 74/141; H10W 90/00; H10W 72/944; H10W 80/312; H10W 80/327; H10W 90/792; H10W 90/794

(57) ABSTRACT

A semiconductor package is provided. The semiconductor package comprises a first semiconductor die including a first surface and a second surface, which are opposite to each other in a vertical direction; a second semiconductor die including a third surface and a fourth surface, which are opposite to each other in the vertical direction, the third surface facing the second surface of the first semiconductor die; a first bonding layer in contact with the first surface of the first semiconductor die; and a second bonding layer disposed between the second surface of the first semiconductor die and the third surface of the second semiconductor die, the second bonding layer being in contact with the second surface of the first semiconductor die, wherein a width of the first bonding layer in a horizontal direction is smaller than a width of the second bonding layer in the horizontal direction, wherein the width of the second bonding layer in the horizontal direction is greater than a width of the first semiconductor die in the horizontal direction.

### CROSS-REFERENCE TO RELATED APPLICATION

This application claims priority from Korean Patent Application No. 10-2024-0155470 filed on Nov. 5, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor package.

### Description of the Related Art

Many modern electronic devices use integrated chips formed on semiconductor wafers during semiconductor device manufacturing processes. Gradually, the semiconductor wafers may be stacked and bonded together to form multi-dimensional (e.g., three-dimensional) integrated chips. The multi-dimensional integrated chips have many advantages over conventional two-dimensional integrated chips, such as higher device density, faster speed, and lower power consumption.

### BRIEF SUMMARY

An object of the present disclosure is to provide a semiconductor package capable of improving device performance and reliability.

According to an aspect of the present disclosure, a semiconductor package includes a first semiconductor die including a first surface and a second surface, which are opposite to each other in a vertical direction; a second semiconductor die including a third surface and a fourth surface, which are opposite to each other in the vertical direction, the third surface facing the second surface of the first semiconductor die; a first bonding layer that in in contact with the first surface of the first semiconductor die; and a second bonding layer disposed between the second surface of the first semiconductor die and the third surface of the second semiconductor die, the second bonding layer being in contact with the second surface of the first semiconductor die, wherein a width of the first bonding layer in a horizontal direction is smaller than a width of the second bonding layer in the horizontal direction, and wherein the a width of the second bonding layer in the horizontal direction is greater than the a width of the first semiconductor die in the horizontal direction.

According to an aspect of the present disclosure, a semiconductor package includes a first semiconductor die including a first surface and a second surface, which are opposite to each other in a vertical direction; a second semiconductor die including a third surface and a fourth surface, which are opposite to each other in the vertical direction, the third surface facing the second surface of the first semiconductor die; a first bonding layer that in in contact with the first surface of the first semiconductor die; and a second bonding layer disposed between the second surface of the first semiconductor die and the third surface of the second semiconductor die, the second bonding layer being in contact with the second surface of the first semiconductor die, wherein a width of the first bonding layer in a horizontal direction is greater than a width of the second bonding layer in the horizontal direction, and wherein the width of the second bonding layer in the horizontal direction is greater than a width of the first semiconductor die in the horizontal direction.

According to an aspect of the present disclosure, a semiconductor package includes a base substrate; a first semiconductor die disposed on the base substrate, the first semiconductor die including a first surface and a second surface, which are opposite to each other in a vertical direction; a second semiconductor die having a third surface and a fourth surface, which are opposite to each other in the vertical direction, the third surface facing the second surface of the first semiconductor die; a first bonding layer being in contact with the first surface of the first semiconductor die; a second bonding layer disposed between the second surface of the first semiconductor die and the third surface of the second semiconductor die, the second bonding layer being in contact with the second surface of the first semiconductor die; a third bonding layer being in contact with the third surface of the second semiconductor die and the second bonding layer; a fourth bonding layer being in contact with the fourth surface of the second semiconductor die; and a filling film covering sidewalls of the first semiconductor die and the second semiconductor die and, the filling film being in contact with the first bonding layer and the fourth bonding layer, wherein a width of the first bonding layer in a horizontal direction is greater than a width of the second bonding layer in the horizontal direction, and wherein the width of the second bonding layer in the horizontal direction is the same as a width of the first semiconductor die in the horizontal direction.

According to an aspect of the present disclosure, a method of manufacturing a semiconductor package includes bonding a first semiconductor die to a first substrate using a first bonding layer that is on a first surface of the first semiconductor die between the first semiconductor die and the first substrate; providing a first filling film covering the first semiconductor die and the first substrate; providing a second bonding layer on a second surface of the first semiconductor die opposite to the first surface; providing a second substrate on the second bonding layer of the first semiconductor die; providing a first support layer to fill a gap between the second bonding layer of the first semiconductor die and the second substrate; removing the first substrate to expose the first bonding layer on the first surface of the first semiconductor die; and bonding a second semiconductor die to the first semiconductor die using the first bonding layer and a third bonding layer that is on a third surface of the second semiconductor die between the second semiconductor die and the first bonding layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail illustrative embodiments thereof with reference to the attached drawings, in which:

FIG. 1 is a view illustrating a semiconductor package according to some embodiments of the present disclosure.

FIG. 2 is an enlarged view illustrating a region A of FIG. 1 to describe a semiconductor package according to some embodiments of the present disclosure.

FIG. 3 is a schematic perspective view illustrating a first semiconductor die, a first bonding layer and a second bonding layer of FIG. 1 to describe a semiconductor package according to some embodiments of the present disclosure.

FIGS. 4 to 22 are views illustrating intermediate steps to describe a method for manufacturing a semiconductor package according to some embodiments of the present disclosure.

### DETAILED DESCRIPTION OF THE DISCLOSURE

Hereinafter, the embodiments according to the present disclosure will be described in detail with reference to the accompanying drawings. The same reference numerals will be used for the same elements on the drawings, and a repeated description of the corresponding elements will be omitted.

In the present disclosure, it will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Spatially relative terms, such as “beneath,” “below,” “lower,” “above,” “upper,” “top,” “bottom,” “on”, and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

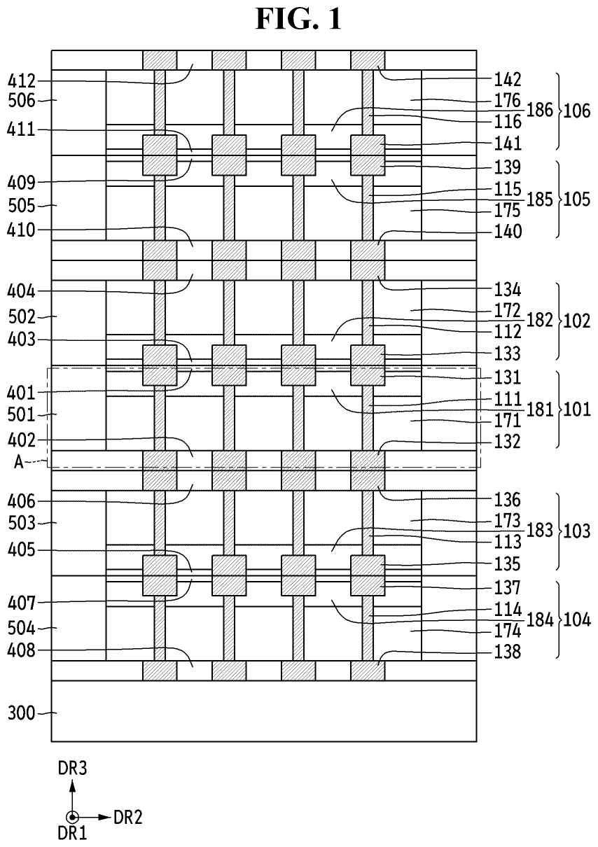

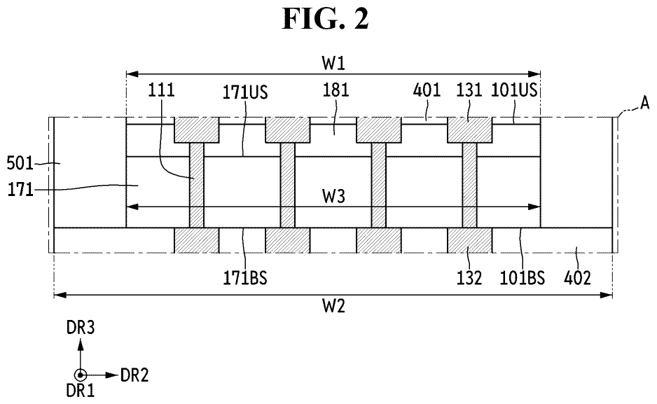

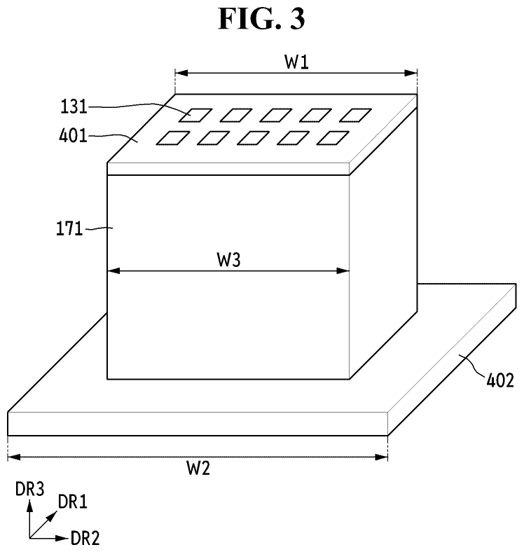

FIG. 1 is a view illustrating a semiconductor package according to some embodiments of the present disclosure. FIG. 2 is an enlarged view illustrating a region A of FIG. 1 to describe a semiconductor package according to some embodiments of the present disclosure. FIG. 3 is a schematic perspective view illustrating a first semiconductor die, a first bonding layer and a second bonding layer of FIG. 1 to describe a semiconductor package according to some embodiments of the present disclosure.

Referring to FIGS. 1 to 3, the semiconductor package according to some embodiments of the present disclosure may include a base substrate 300, a first semiconductor die 101, a second semiconductor die 102, a third semiconductor die 103, a fourth semiconductor die 104, a fifth semiconductor die 105, a sixth semiconductor die 106, a first filling film 501, a second filling film 502, a third filling film 503, a fourth filling film 504, a fifth filling film 505, and a sixth filling film 506.

The base substrate 300 may be a semiconductor substrate. The base substrate 300 may include a direct circuit therein. In detail, the base substrate 300 may include an electronic device such as a transistor. However, as another example, the base substrate 300 may be a substrate, which does not include an electronic device such as a transistor, for example, a printed circuit board (PCB).

The first to sixth semiconductor dies 101, 102, 103, 104, 105 and 106 may be memory chips or logic chips. For example, the first to sixth semiconductor dies 101, 102, 103, 104, 105 and 106 may all be the same type of memory chip. As another example, some of the first to sixth semiconductor dies 101, 102, 103, 104, 105 and 106 may be memory chips, and some other thereof may be logic chips. In some embodiments, the first to sixth semiconductor dies 101, 102, 103, 104, 105 and 106 may be high bandwidth memory (HBM) chips. Although only the first semiconductor die 101 will be described below, the second to sixth semiconductor dies 102, 103, 104, 105 and 106 may also include the same structure.

The fourth semiconductor die 104, the third semiconductor die 103, the first semiconductor die 101, the second semiconductor die 102, the fifth semiconductor die 105 and the sixth semiconductor die 106 may be sequentially stacked in that order on the base substrate 300.

The first semiconductor die 101 may include a first substrate 171, a first bonding pad 131, a second bonding pad 132, a first through via 111, and a first device layer 181.

The first semiconductor die 101 may be disposed between the third semiconductor die 103 and the second semiconductor die 102. The first semiconductor die 101 may include a lower surface 101BS and an upper surface 101US, which are opposite to each other in a third direction DR3. The lower surface 101BS of the first semiconductor die 101 may be disposed to face the third semiconductor die 103, and the upper surface 101US of the first semiconductor die 101 may be disposed to face the second semiconductor die 102.

For reference, in the present specification, first and second directions DR1 and DR2 may cross each other. The first and second directions DR1 and DR2 may be substantially perpendicular to each other. The first and second directions DR1 and DR2 may be parallel with an upper surface of the base substrate 300. For ease of description, the first and second directions DR1 and DR2 may be referred to as horizontal directions. The third direction DR3 may cross the first and second directions DR1 and DR2. The third direction DR3 may be substantially perpendicular to the first and second directions DR1 and DR2. The third direction DR3 may be a direction perpendicular to the upper surface of the base substrate 300. For ease of description, the third direction DR3 may be referred to as a vertical direction.

The first substrate 171 of the first semiconductor die 101 may be, for example, a silicon (Si) wafer containing crystalline silicon, polycrystalline silicon or amorphous silicon. As another example, the first substrate 171 may include a semiconductor element such as germanium (Ge), or a compound semiconductor such as silicon carbide (SiC), gallium arsenide (GaAs), indium arsenide (InAs), and indium phosphide (InP).

The first substrate 171 may have a silicon-on-insulator (SOI) structure. For example, the first substrate 171 may include a buried oxide (BOX) layer. In some embodiments, the first substrate 171 may include a conductive region, for example, an impurity-doped well or an impurity-doped structure. Also, the first substrate 171 may have various device isolation structures such as a shallow trench isolation (STI) structure.

The first substrate 171 may include an upper surface 171US and a lower surface 171BS, which are opposite to each other. The upper surface 171US of the first substrate 171 may be disposed to face the second semiconductor die 102, and the lower surface 171BS of the first substrate 171 may be disposed to face the third semiconductor die 103. The lower surface 171BS of the first substrate 171 may be disposed on the same plane as the lower surface 101BS of the first semiconductor die 101.

The first device layer 181 may be disposed on the upper surface 171US of the first substrate 171. For example, the first device layer 181 may be a memory circuit, a logic circuit, or their combination. As another example, each of the first device layers 181 may be or include a metal oxide semiconductor field effect transistor (MOSFET), a high voltage transistor, a bipolar junction transistor (BJT), an n-channel metal oxide semiconductor (nMOS) transistor, a p-channel metal oxide semiconductor (pMOS) transistor, a gate-all-around FET (GAAFET), a gate surround FET, a multi-bridge channel FET (MBCFET), a nanowire FET, a nano-ring FET, a nanosheet field-effect transistor (NSFET) or the like.

Although not shown, the first device layer 181 may be covered by an insulating film. The insulating film covering the first device layer 181 may include at least one of, for example, silicon oxide, silicon nitride or silicon oxynitride.

The first bonding pad 131 may be disposed on the upper surface 171US of the first substrate 171. The first bonding pad 131 may be disposed on the first device layer 181. The second bonding pad 132 may be disposed on the lower surface 171BS of the first substrate 171. The first bonding pad 131 and the second bonding pad 132 may include copper (Cu).

The first through via 111 passing through the first substrate 171 may be disposed inside the first substrate 171. The first through via 111 may electrically connect the first bonding pad 131 to the second bonding pad 132. In some embodiments, the first through via 111 may be a through silicon via TSV.

Although not shown, an alignment key may be disposed in the first semiconductor die 101. The alignment key may align the first semiconductor die 101 with the second semiconductor die 102, which will be described later, in the second direction DR2. The alignment key may align the first semiconductor die 101 with the third semiconductor die 103, which will be described later, in the second direction DR2. The alignment key may include, for example, copper (Cu).

A first bonding layer 401 may be disposed on the upper surface 101US of the first semiconductor die 101. In detail, the first bonding layer 401 may be disposed on the first device layer 181. The first bonding layer 401 may be penetrated by the first bonding pad 131. In other words, the first bonding pad 131 may pass through the first bonding layer 401. The first bonding layer 401 may include at least one of, for example, silicon nitride (SiN), silicon oxycarbide (SiOC), silicon carbonated hydride (SiCOH), silicon carbon nitride (SiCN), silicon oxide (SiO), aluminum nitride (AIN), aluminum oxide (AIO), or their combination, but is not limited thereto.

A width W1 of the first bonding layer 401 in the second direction DR2 may be the same as a width W3 of the first substrate 171 in the second direction DR2. In other words, the width W1 of the first bonding layer 401 in the second direction DR2 may be the same as a width W3 of the first semiconductor die 101 in the second direction DR2. However, the inventive concept is not limited thereto, and the width W1 of the first bonding layer 401 may be greater than the width W3 of the first semiconductor die 101. Although FIG. 1 and FIG. 2 show that the first bonding layer 401 is disconnected by the first bonding pad 131, this is only expressed by a cross-sectional view. Referring to FIG. 3, the width W1 of the first bonding layer 401 in the second direction DR2 may be the same as the width W3 of the first substrate 171 in the second direction DR2.

A second bonding layer 402 may be disposed on the lower surface 171BS of the first substrate 171. The second bonding layer 402 may be penetrated by the second bonding pad 132. In other words, the second bonding pad 132 may pass through the second bonding layer 402. The second bonding layer 402 may include at least one of, for example, silicon nitride (SiN), silicon oxycarbide (SiOC), silicon carbonated hydride (SiCOH), silicon carbon nitride (SiCN), silicon oxide (SiO), aluminum nitride (AlN), aluminum oxide (AlO), or their combination, but is not limited thereto.

A width W2 of the second bonding layer 402 in the second direction DR2 may be greater than the width W3 of the first substrate 171 in the second direction DR2. Although FIG. 1 and FIG. 2 show that the second bonding layer 402 is disconnected by the second bonding pad 132, this is only expressed by a cross-sectional view. Referring to FIG. 3, the width W2 of the second bonding layer 402 in the second direction DR2 may be greater than the width W3 of the first substrate 171 in the second direction DR2. The width W2 of the second bonding layer 402 in the second direction DR2 may be greater than the width W1 of the first bonding layer 401 in the second direction DR2.

Hereinafter, for convenience of description, the second semiconductor die 102 will be described based on differences from the first semiconductor die 101. The second semiconductor die 102 may include a second substrate 172, a third bonding pad 133, a fourth bonding pad 134, a second through via 112, and a second device layer 182.

The second semiconductor die 102 may be disposed between the first semiconductor die 101 and the fifth semiconductor die 105. The second semiconductor die 102 may include two surfaces opposite to each other in the third direction DR3. One surface of the second semiconductor die 102 may be disposed to face the first semiconductor die 101, and the other surface of the second semiconductor die 102 may be disposed to face the fifth semiconductor die 105.

The second substrate 172 may include an upper surface and a lower surface, which are opposite to each other. The upper surface of the second substrate 172 may be disposed to face the fifth semiconductor die 105, and the lower surface of the second substrate 172 may be disposed to face the first semiconductor die 101. The upper surface of the second substrate 172 may be disposed on the same plane as the upper surface of the second semiconductor die 102.

The second device layer 182 may be disposed on the lower surface of the second substrate 172. The third bonding pad 133 may be disposed on the lower surface of the second substrate 172. The fourth bonding pad 134 may be disposed on the upper surface of the second substrate 172. The third bonding pad 133 may be disposed on the second device layer 182.

The second through via 112 passing through the second substrate 172 may be disposed inside the second substrate 172. The second through via 112 may electrically connect the third bonding pad 133 to the fourth bonding pad 134.

Although not shown, an alignment key may be disposed in the second semiconductor die 102. The alignment key may align the second semiconductor die 102 with the first semiconductor die 101 in the second direction DR2. The alignment key may align the second semiconductor die 102 with the fifth semiconductor die 105 in the second direction DR2.

A third bonding layer 403 may be disposed on the lower surface of the second semiconductor die 102. In detail, the third bonding layer 403 may be disposed on the second device layer 182. The third bonding layer 403 may be penetrated by the third bonding pad 133. In other words, the third bonding pad 133 may pass through the third bonding layer 403. A width of the third bonding layer 403 may be the same as a width of the second semiconductor die 102 in the second direction DR2. However, the inventive concept is not limited thereto, and the width of the third bonding layer 403 may be greater than the width of the second semiconductor die 102 in the second direction DR2.

A fourth bonding layer 404 may be disposed on the upper surface of the second substrate 172. The fourth bonding layer 404 may be penetrated by the fourth bonding pad 134. In other words, the fourth bonding pad 134 may pass through the fourth bonding layer 404.

Hereinafter, for convenience of description, the third semiconductor die 103 will be described based on differences from the first semiconductor die 101. The third semiconductor die 103 may include a third substrate 173, a fifth bonding pad 135, a sixth bonding pad 136, a third through via 113, and a third device layer 183.

The third semiconductor die 103 may be disposed between the first semiconductor die 101 and the fourth semiconductor die 104. The third semiconductor die 103 may include two surfaces opposite to each other in the third direction DR3. One surface of the third semiconductor die 103 may be disposed to face the first semiconductor die 101, and the other surface thereof may be disposed to face the fourth semiconductor die 104.

The third substrate 173 may include an upper surface and a lower surface, which are opposite to each other. The upper surface of the third substrate 173 may be disposed to face the first semiconductor die 101, and the lower surface of the third substrate 173 may be disposed to face the fourth semiconductor die 104. The upper surface of the third substrate 173 may be disposed on the same plane as the upper surface of the third semiconductor die 103.

The third device layer 183 may be disposed on the lower surface of the third substrate 173. The fifth bonding pad 135 may be disposed on the lower surface of the third substrate 173. The fifth bonding pad 135 may be disposed on the third device layer 183. The sixth bonding pad 136 may be disposed on the upper surface of the third substrate 173.

The third through via 113 passing through the third substrate 173 may be disposed inside the third substrate 173. The third through via 113 may electrically connect the fifth bonding pad 135 to the sixth bonding pad 136.

Although not shown, an alignment key may be disposed in the third semiconductor die 103. The alignment key may align the third semiconductor die 103 with the first semiconductor die 101 in the second direction DR2. The alignment key may align the third semiconductor die 103 with the fourth semiconductor die 104 in the second direction DR2.

A fifth bonding layer 405 may be disposed on the lower surface of the third substrate 173. In detail, the fifth bonding layer 405 may be disposed on the third device layer 183. The fifth bonding layer 405 may be penetrated by the fifth bonding pad 135. In other words, the fifth bonding pad 135 may pass through the fifth bonding layer 405.

A sixth bonding layer 406 may be disposed on the upper surface of the third substrate 173. The sixth bonding layer 406 may be penetrated by the sixth bonding pad 136. In other words, the sixth bonding pad 136 may pass through the sixth bonding layer 406.

Hereinafter, for convenience of description, the fourth semiconductor die 104 will be described based on differences from the first semiconductor die 101. The fourth semiconductor die 104 may include a fourth substrate 174, a seventh bonding pad 137, an eighth bonding pad 138, a fourth through via 114, and a fourth device layer 184.

The fourth semiconductor die 104 may be disposed between the third semiconductor die 103 and the base substrate 300. The fourth semiconductor die 104 may include two surfaces opposite to each other in the third direction DR3. One surface of the fourth semiconductor die 104 may be disposed to face the third semiconductor die 103, and the other surface thereof may be disposed to face the base substrate 300.

The fourth substrate 174 may include an upper surface and a lower surface, which are opposite to each other. The upper surface of the fourth substrate 174 may be disposed to face the third semiconductor die 103, and the lower surface of the fourth substrate 174 may be disposed to face the base substrate 300. The lower surface of the fourth substrate 174 may be disposed on the same plane as the lower surface of the fourth semiconductor die 104.

The fourth device layer 184 may be disposed on the upper surface of the fourth substrate 174. The seventh bonding pad 137 may be disposed on the upper surface of the fourth substrate 174. The seventh bonding pad 137 may be disposed on the fourth device layer 184. The eighth bonding pad 138 may be disposed on the lower surface of the fourth substrate 174.

The fourth through via 114 passing through the fourth substrate 174 may be disposed inside the fourth substrate 174. The fourth through via 114 may electrically connect the seventh bonding pad 137 to the eighth bonding pad 138.

Although not shown, an alignment key may be disposed in the fourth semiconductor die 104. The alignment key may align the fourth semiconductor die 104 with the third semiconductor die 103 in the second direction DR2. The alignment key may align the fourth semiconductor die 104 with the base substrate 300 in the second direction DR2.

A seventh bonding layer 407 may be disposed on the upper surface of the fourth semiconductor die 104. In detail, the seventh bonding layer 407 may be disposed on the fourth device layer 184. The seventh bonding layer 407 may be penetrated by the seventh bonding pad 137. In other words, the seventh bonding pad 137 may pass through the seventh bonding layer 407.

An eighth bonding layer 408 may be disposed on the lower surface of the fourth substrate 174. The eighth bonding layer 408 may be penetrated by the eighth bonding pad 138. In other words, the eighth bonding pad 138 may pass through the eighth bonding layer 408.

Hereinafter, for convenience of description, the fifth semiconductor die 105 will be described based on differences from the first semiconductor die 101. The fifth semiconductor die 105 may include a fifth substrate 175, a ninth bonding pad 139, a tenth bonding pad 140, a fifth through via 115, and a fifth device layer 185.

The fifth semiconductor die 105 may be disposed between the second semiconductor die 102 and the sixth semiconductor die 106. The fifth semiconductor die 105 may include two surfaces opposite to each other in the third direction DR3. One surface of the fifth semiconductor die 105 may be disposed to face the second semiconductor die 102, and the other surface thereof may be disposed to face the sixth semiconductor die 106.

The fifth substrate 175 may include an upper surface and a lower surface, which are opposite to each other. The lower surface of the fifth substrate 175 may be disposed to face the second semiconductor die 102, and the upper surface of the fifth substrate 175 may be disposed to face the sixth semiconductor die 106. The lower surface of the fifth substrate 175 may be disposed on the same plane as the lower surface of the fifth semiconductor die 105.

The fifth device layer 185 may be disposed on the upper surface of the fifth substrate 175. The ninth bonding pad 139 may be disposed on the upper surface of the fifth substrate 175. The ninth bonding pad 139 may be disposed on the fifth device layer 185. The tenth bonding pad 140 may be disposed on the lower surface of the fifth substrate 175.

The fifth through via 115 passing through the fifth substrate 175 may be disposed inside the fifth substrate 175. The fifth through via 115 may electrically connect the ninth bonding pad 139 to the tenth bonding pad 140.

An alignment key may be disposed in the fifth semiconductor die 105. The alignment key may align the fifth semiconductor die 105 with the second semiconductor die 102 in the second direction DR2. The alignment key may align the fifth semiconductor die 105 with the sixth semiconductor die 106 in the second direction DR2.

A ninth bonding layer 409 may be disposed on the upper surface of the fifth semiconductor die 105. In detail, the ninth bonding layer 409 may be disposed on the fifth device layer 185. The ninth bonding layer 409 may be penetrated by the ninth bonding pad 139. In other words, the ninth bonding pad 139 may pass through the ninth bonding layer 409.

A tenth bonding layer 410 may be disposed on the lower surface of the fifth substrate 175. The tenth bonding layer 410 may be penetrated by the tenth bonding pad 140. In other words, the tenth bonding pad 140 may pass through the tenth bonding layer 410.

Hereinafter, for convenience of description, the sixth semiconductor die 106 will be described based on differences from the first semiconductor die 101. The sixth semiconductor die 106 may include a sixth substrate 176, an eleventh bonding pad 141, a twelfth bonding pad 142, a sixth through via 116, and a sixth device layer 186.

The sixth semiconductor die 106 may be disposed on the fifth semiconductor die 105. The sixth semiconductor die 106 may include two surfaces opposite to each other in the third direction DR3. One surface of the sixth semiconductor die 106 may be disposed to face the fifth semiconductor die 105. Although FIG. 1 shows that no other semiconductor die is disposed on the sixth semiconductor die 106, the embodiment of the present disclosure is not limited thereto. As another example, one or more semiconductor dies may be further disposed on the sixth semiconductor die 106.

The sixth substrate 176 may include an upper surface and a lower surface, which are opposite to each other. The lower surface of the sixth substrate 176 may be disposed to face the fifth semiconductor die 105. The upper surface of the sixth substrate 176 may be disposed on the same plane as the upper surface of the sixth semiconductor die 106.

The sixth device layer 186 may be disposed on the lower surface of the sixth substrate 176. The eleventh bonding pad 141 may be disposed on the lower surface of the sixth substrate 176. The eleventh bonding pad 141 may be disposed on the sixth device layer 186. The twelfth bonding pad 142 may be disposed on the upper surface of the sixth substrate 176.

The sixth through via 116 passing through the sixth substrate 176 may be disposed inside the sixth substrate 176. The sixth through via 116 may electrically connect the eleventh bonding pad 141 to the twelfth bonding pad 142.

Although not shown, an alignment key may be disposed in the sixth semiconductor die 106. The alignment key may align the sixth semiconductor die 106 with the first semiconductor die 101 in the second direction DR2.

An eleventh bonding layer 411 may be disposed on the lower surface of the sixth semiconductor die 106. In detail, the eleventh bonding layer 411 may be disposed on the sixth device layer 186. The eleventh bonding layer 411 may be penetrated by the eleventh bonding pad 141. In other words, the eleventh bonding pad 141 may pass through the eleventh bonding layer 411.

A twelfth bonding layer 412 may be disposed on the upper surface of the sixth substrate 176. The twelfth bonding layer 412 may be penetrated by the twelfth bonding pad 142. In other words, the twelfth bonding pad 142 may pass through the twelfth bonding layer 412.

The first to sixth filling films 501, 502, 503, 504, 505 and 506 may cover sidewalls of the first to sixth semiconductor dies 101, 102, 103, 104, 105 and 106, respectively. The first to sixth filling films 501, 502, 503, 504, 505 and 506 may include, for example, silicon oxide (SiO), but are not limited thereto.

FIG. 1 shows that the first to sixth filling films 501, 502, 503, 504, 505 and 506 are separated from the plurality of bonding layers 402, 404, 406, 408, 410 and 412, but the present disclosure is not limited thereto. As another example, when the first to sixth filling films 501, 502, 503, 504, 505 and 506 and the plurality of bonding layers 402, 404, 406, 408, 410 and 412 commonly include silicon oxide (SiO), a boundary between the first to sixth filling films 501, 502, 503, 504, 505 and 506 and the plurality of bonding layers 402, 404, 406, 408, 410, and 412 may not be exposed.

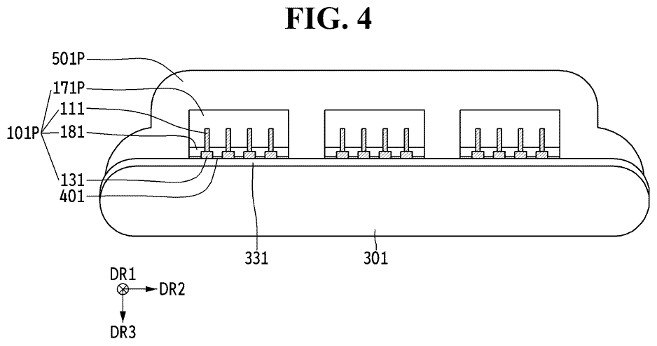

FIGS. 4 to 22 are views illustrating intermediate steps to describe a method for manufacturing a semiconductor package according to some embodiments of the present disclosure. For convenience of description, the following description in FIGS. 4 to 22 will be based on differences from the description made in FIGS. 1 to 3.

Referring to FIG. 4, a first carrier substrate 301, on which a plurality of first pre-semiconductor dies 101P are packaged, may be provided. In detail, a first pre-semiconductor die 101P, in which a first bonding pad 131, a first through electrode 111 and a first device layer 181 are formed in a first pre-substrate 171P, may be provided on the first carrier substrate 301. For example, the first carrier substrate 301 may include a silicon-based material such as glass or silicon oxide, an organic material, other material such as aluminum oxide, or any combination thereof.

The first through electrode 111 may be formed by, for example, CVD, PVD, sputtering, electroless plating, ion implantation, other suitable film formation or growth process, or any combination thereof. An upper surface of the first through electrode 111 may not be exposed. In other words, the upper surface of the first through electrode 111 may be covered by the first pre-substrate 171P. For example, the first through electrode 111 may not penetrate all the way through the first pre-substrate 171P in the vertical direction.

Although not shown, an alignment key may be disposed in the first carrier substrate 301. The first pre-semiconductor die 101P may be aligned on the first carrier substrate 301 by the alignment key.

A first carrier bonding layer 331 may be disposed on an upper surface of the first carrier substrate 301. The first carrier bonding layer 331 may be disposed between the first carrier substrate 301 and the first pre-semiconductor die 101P. The first pre-semiconductor die 101P may be stably fixed onto the first carrier substrate 301 by the first carrier bonding layer 331. The first bonding layer 401 may be disposed on a lower surface of the first pre-semiconductor die 101P. The first pre-semiconductor die 101P may be stably fixed onto the first carrier substrate 301 by the first bonding layer 401. For example, lower surfaces of the first bonding layer 401 and the first bonding pad 131 may be affixed to the upper surface of the first carrier bonding layer 331.

A first pre-filling film 501P covering the upper surface of the first carrier substrate 301 and the first pre-semiconductor die 101P may be formed. The first pre-filling film 501P may cover sidewalls and an upper surface of the first semiconductor die 101. For example, the first pre-filling film 501P may be formed by chemical vapor deposition (CVD).

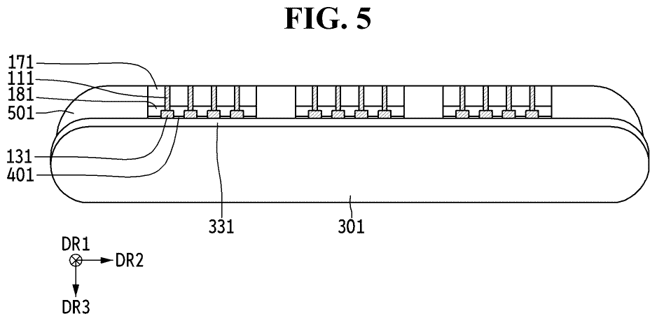

Referring to FIG. 5, an upper surface of the first pre-substrate (see 171P of FIG. 4) may be removed, and the first substrate 171 may be formed. For example, the process of removing the upper surface of the first pre-substrate 171P may include a grinding process.

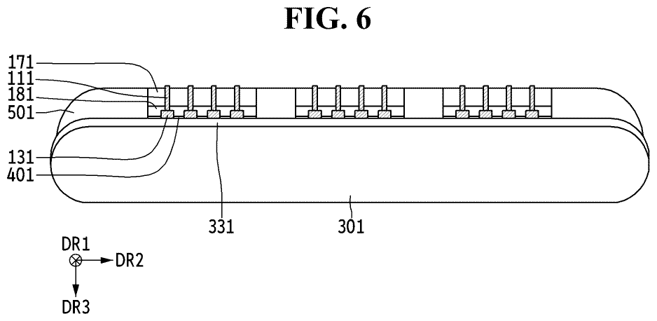

Subsequently, referring to FIG. 6, the upper surface of the first substrate 171 may be removed, and the upper surface of the first through via 111 may be exposed. For example, the process of removing the upper surface of the first substrate 171 may include a chemical mechanical polishing process.

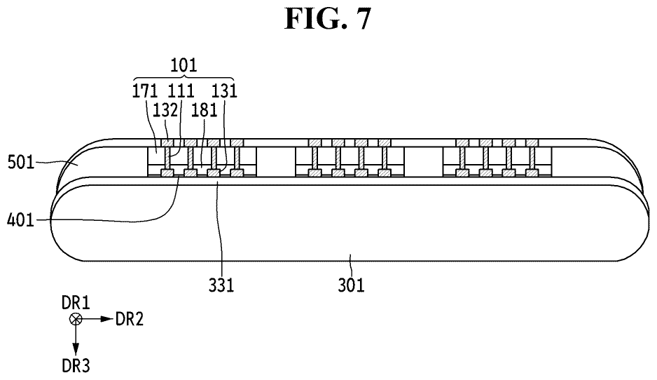

Referring to FIG. 7, the second bonding pad 132 may be formed to form the first semiconductor die 101, and the second bonding layer 402 may be formed on the first filling film 501. In detail, the second bonding pad 132 may be formed on the upper surface of the first substrate 171. The process of forming the second bonding pad 132 may be formed by, for example, one or more film formation processes, one or more patterning processes, one or more planarization processes, some other suitable manufacturing processes, or any combination thereof.

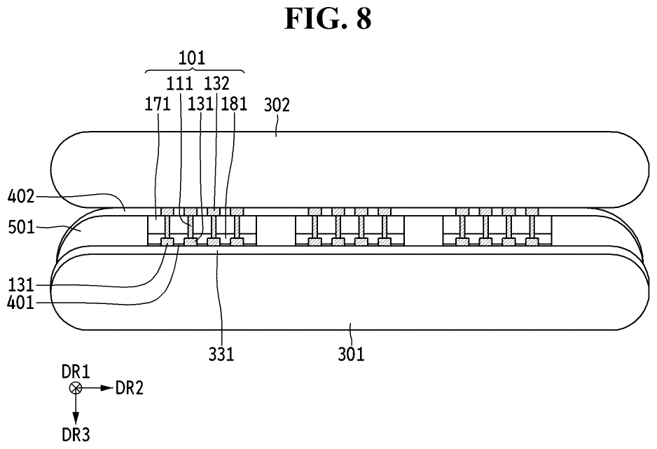

Subsequently, referring to FIG. 8, a second carrier substrate 302 may be bonded onto the first semiconductor die 101. In other words, the first semiconductor die 101 may be disposed between the first carrier substrate 301 and the second carrier substrate 302.

Although not shown, an alignment key may be disposed in the second carrier substrate 302. The second carrier substrate 302 may be aligned on the first semiconductor die 101 by the alignment key.

The second carrier substrate 302 may include, for example, a silicon-based material such as glass or silicon oxide, an organic material, or other material such as aluminum oxide, any combination of these materials, and the like.

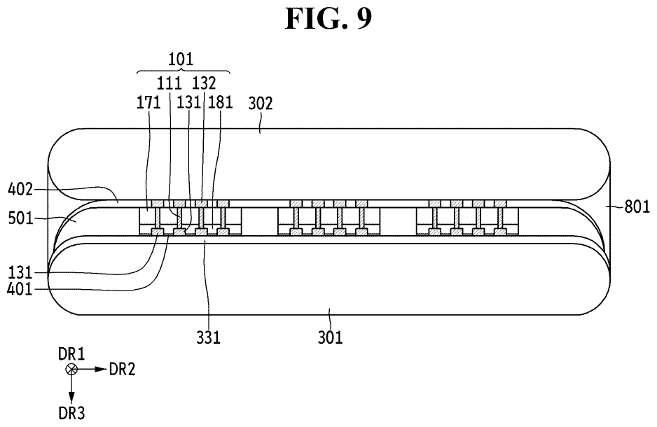

Referring to FIG. 9, a first support layer 801 may be formed between the first carrier substrate 301 and the second carrier substrate 302. The first support layer 801 may be formed on an upper surface of the second bonding layer 402 and an upper surface of the first carrier bonding layer 331. The process of forming the first support layer 801 may include, for example, a process of injecting a support material from an external region. The first support layer 801 may include, for example, epoxy, polymer, silicon, some other suitable material, or any combination thereof. For example, when a liquid is injected to form the first support layer 801, the process of forming the first support layer 801 may include a process of curing a support material of a liquid state.

The first support layer 801 may be formed on the upper surface of the second bonding layer 402 and the upper surface of the first carrier bonding layer 331 to provide structural support for the semiconductor structures. Therefore, the first support layer 801 may prevent damage to the semiconductor package.

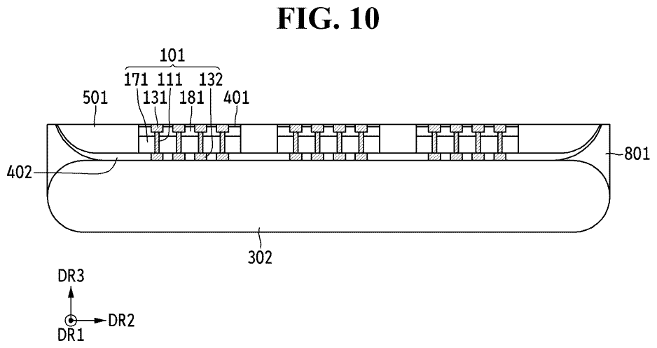

Referring to FIG. 10, the first carrier substrate (see 301 of FIG. 9) may be de-bonded. The first carrier substrate 301 may be de-bonded so that one surface of the first semiconductor die 101 may be exposed. In detail, the first bonding pad 131 and the first bonding layer 401 of the first semiconductor die 101 may be exposed.

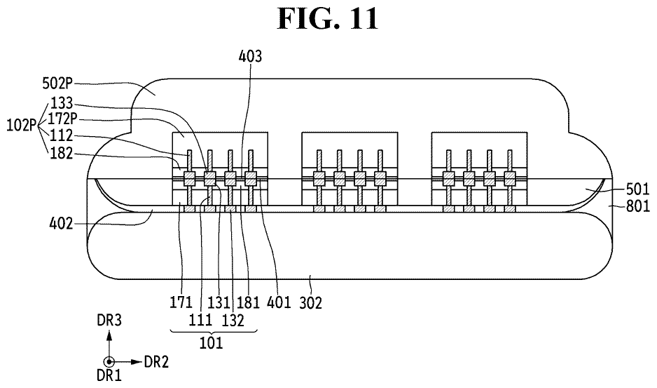

Referring to FIG. 11, a second pre-semiconductor die 102P may be stacked on the upper surface of the first semiconductor die 101. A second pre-semiconductor die 102P, in which a third bonding pad 133, a second through electrode 112 and a second device layer 182 are formed in a second pre-substrate 172P, may be provided on the first semiconductor die 101. The second through electrode 112 may be formed by, for example, CVD, PVD, sputtering, electroless plating, ion implantation, other suitable film formation or growth process, or any combination thereof. The upper surface of the second through electrode 112 may not be exposed. In other words, the upper surface of the second through electrode 112 may be covered by the second pre-substrate 172P. For example, the second through electrode 112 may not penetrate all the way through the second pre-substrate 172P in the vertical direction.

Although not shown, an alignment key may be disposed in the second pre-substrate 172P. The second pre-semiconductor die 102P may be aligned on the first semiconductor die 101 by the alignment key.

A second pre-filling film 502P covering the upper surface of the first filling film 501, the upper surface of the first support layer and the second pre-semiconductor die 102P may be formed. The second pre-filling film 502P may cover sidewalls and an upper surface of the second semiconductor die 102. For example, the second pre-filling film 502P may be formed by chemical vapor deposition (CVD).

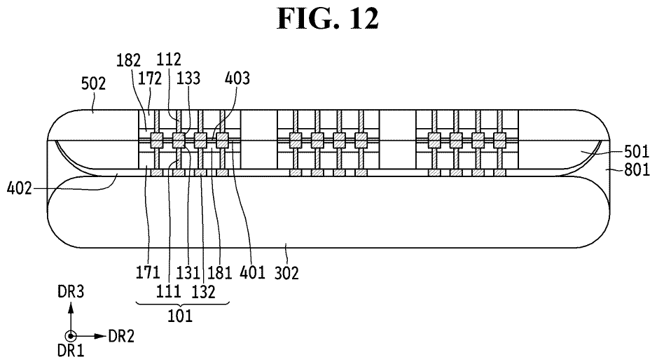

Referring to FIG. 12, an upper surface of the second pre-substrate (see 172P of FIG. 11) may be removed, and the second substrate 172 may be formed. For example, the process of removing the upper surface of the second pre-substrate 172P may include a grinding process.

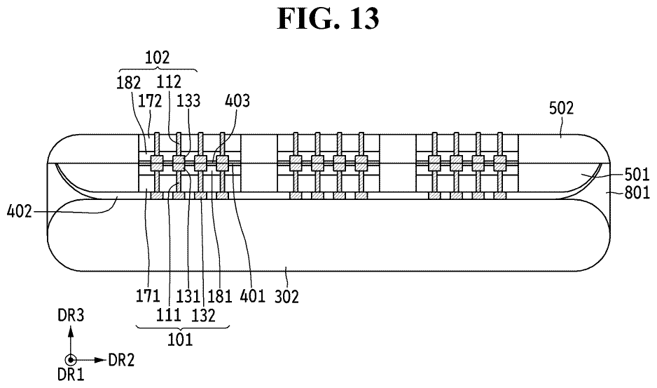

Subsequently, referring to FIG. 13, the upper surface of the second substrate 172 may be removed, and the upper surface of the second through via 112 may be exposed. For example, the process of removing the upper surface of the second substrate 172 may include a chemical mechanical polishing process.

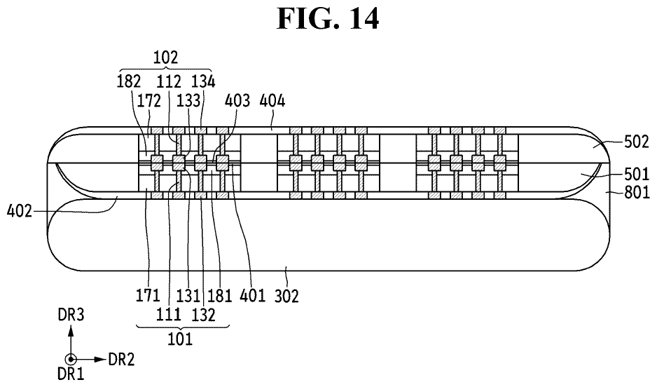

Referring to FIG. 14, the fourth bonding pad 134 may be formed to form the second semiconductor die 102, and the fourth bonding layer 404 may be formed on the second filling film 502. In detail, the fourth bonding pad 134 may be formed on the upper surface of the second substrate 172. The process of forming the fourth bonding pad 134 may be formed by, for example, one or more film formation processes, one or more patterning processes, one or more planarization processes, some other suitable manufacturing processes, or any combination thereof.

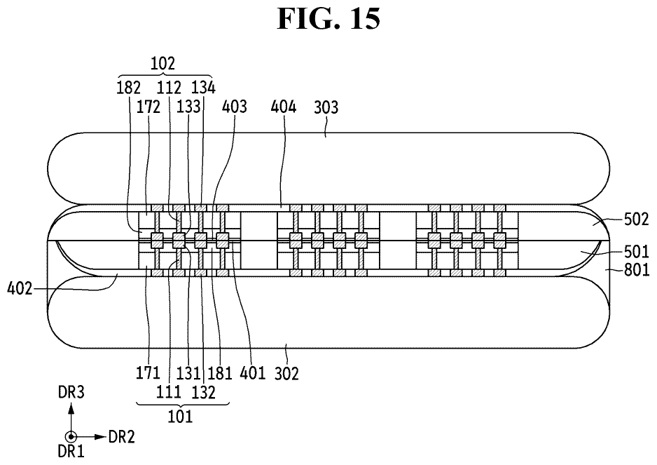

Subsequently, referring to FIG. 15, a third carrier substrate 303 may be bonded onto the second semiconductor die 102. In other words, the second semiconductor die 102 may be disposed between the first semiconductor die 101 and the third carrier substrate 303.

The third carrier substrate 303 may include, for example, a silicon-based material such as glass or silicon oxide, an organic material, or other material such as aluminum oxide, or any combination thereof.

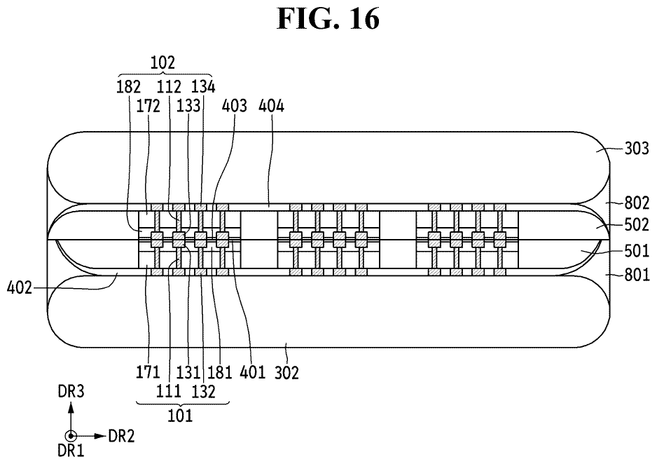

Referring to FIG. 16, a second support layer 802 may be formed between the second semiconductor die 102 and the third carrier substrate 303 (e.g., between the second filling film 502 and the third carrier substrate 303). The second support layer 802 may be formed on an upper surface of the fourth bonding layer 404. The process of forming the second support layer 802 may include, for example, a process of injecting a support material from an external region. The second support layer 802 may include, for example, epoxy, polymer, silicon, some other suitable material, or any combination thereof. For example, when a liquid is injected to form the second support layer 802, the process of forming the second support layer 802 may include a process of curing a support material of a liquid state.

The second support layer 802 may be formed between the second semiconductor die 102 and the third carrier substrate 303 to provide structural support for the semiconductor structures. Therefore, the second support layer 802 may prevent damage to the semiconductor package.

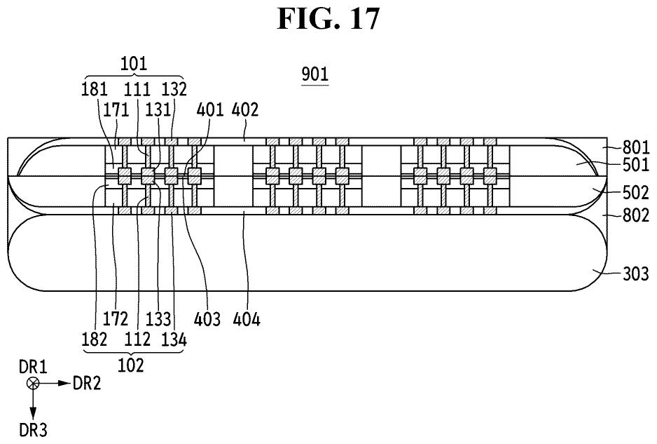

Referring to FIG. 17, a first stacked structure 901 from which the second carrier substrate (see 302 of FIG. 16) is de-bonded may be formed. The second carrier substrate 302 may be de-bonded so that one surface of the first semiconductor die 101 may be exposed. In detail, the second bonding pad 132 and the second bonding layer 402 of the first semiconductor die 101 may be exposed.

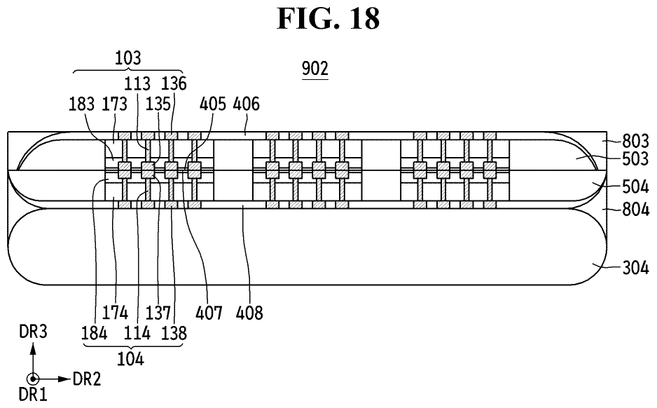

Referring to FIG. 18, a second stacked structure 902 in which a fourth carrier substrate 304, a fourth semiconductor die 104 and a third semiconductor die 103 are sequentially stacked may be provided. In other words, the fourth semiconductor die 104 may be disposed between the fourth carrier substrate 304 and the third semiconductor die 103. The fourth carrier substrate 304 may include, for example, a silicon-based material such as glass or silicon oxide, an organic material, or other material such as aluminum oxide, or any combination thereof.

The process of stacking the third semiconductor die 103 and the fourth semiconductor die 104 on the fourth carrier substrate 304 may be the same as the above-described process of stacking the first semiconductor die 101 and the second semiconductor die 102 on the third carrier substrate 303.

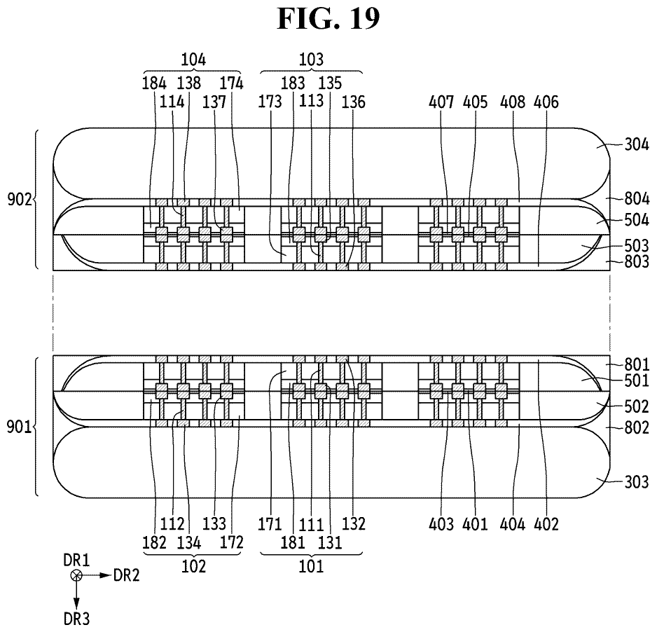

Referring to FIG. 19, the second stacked structure 902 may be disposed on the first stacked structure 901 to face the first stacked structure 901. For example, the second bonding layer 402 of the first stacked structure 901 and the sixth bonding layer 406 of the second stacked structure 902 may be disposed to face each other. In this case, the first support layer 801 and the third support layer 803 may be disposed to face each other.

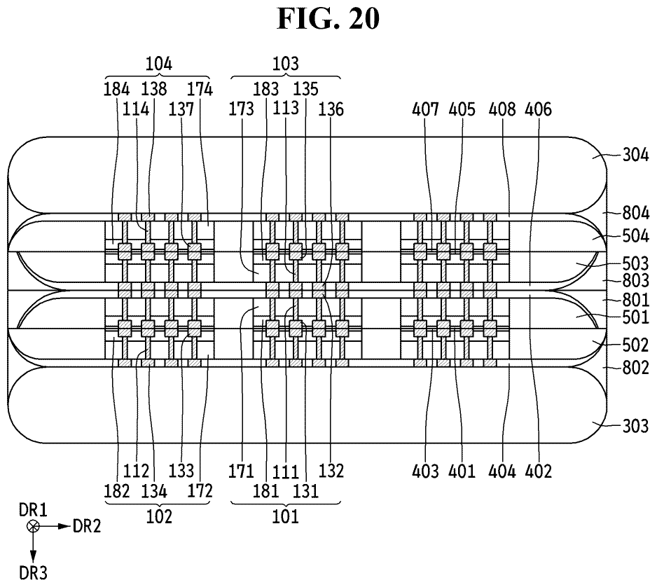

Subsequently, referring to FIG. 20, the first stacked structure 901 and the second stacked structure 902 may be bonded to each other. In other words, the second semiconductor die 102, the first semiconductor die 101, the third semiconductor die 103, the fourth semiconductor die 104 and the fourth carrier substrate 304 may be sequentially disposed on the third carrier substrate 303. The first stacked structure 901 and the second stacked structure 902 may be bonded to each other by the second bonding layer 402 and the sixth bonding layer 406.

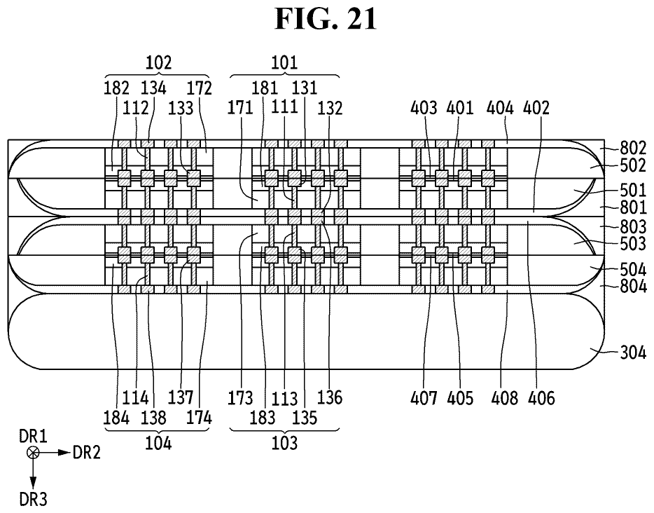

Referring to FIG. 21, the third carrier substrate 303 may be de-bonded. The third carrier substrate 303 may be de-bonded to expose upper surfaces of the fourth bonding layer 404, the fourth bonding pad 134 and the second filling film 502.

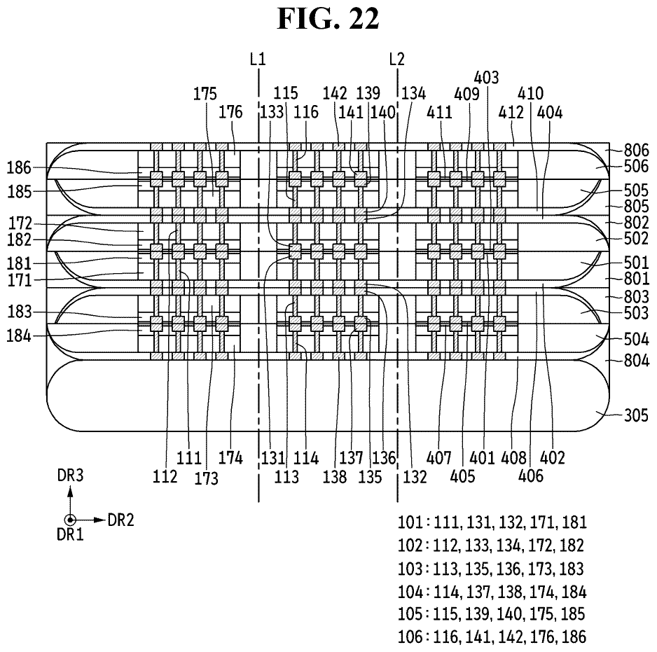

Subsequently, referring to FIG. 22, the fifth semiconductor die 105 and the sixth semiconductor die 106 may be sequentially stacked on the second semiconductor die 102. In other words, the fourth semiconductor die 104, the third semiconductor die 103, the first semiconductor die 101, the second semiconductor die 102, the fifth semiconductor die 105 and the sixth semiconductor die 106 may be sequentially stacked on the fifth carrier substrate 305. The fifth carrier substrate 305 may include, for example, a silicon-based material such as glass or silicon oxide, an organic material, or other material such as aluminum oxide, or any combination thereof.

The process of stacking the fifth semiconductor die 105 and the sixth semiconductor die 106 may be the same as, for example, the above-described process of stacking the third and fourth semiconductor dies 103 and 104 on the first and second semiconductor dies 101 and 102. After the fifth semiconductor die 105 and the sixth semiconductor die 106 are sequentially stacked on the second semiconductor die 102, a dicing process may be performed along a first dicing line L1 and a second dicing line L2.

Subsequently, referring to FIG. 1, the fifth carrier substrate (see 305 of FIG. 22) may be de-bonded, and the first to sixth semiconductor dies 101, 102, 103, 104, 105 and 106 may be packaged on the base substrate 300. In other words, the fourth semiconductor die 104, the third semiconductor die 103, the second semiconductor die 102, the fifth semiconductor die 105 and the sixth semiconductor die 106 may be sequentially stacked on the base substrate 300.

Since the first to fifth filling films 501, 502, 503, 504, 505 and 506 are formed on the base substrate 300 after the first to fifth semiconductor dies 101, 102, 103, 104, 105 and 106 are formed thereon, warpage of the semiconductor package may be prevented.

In concluding the detailed description, those skilled in the art will appreciate that many variations and modifications may be made to the preferred embodiments without substantially departing from the principles of the present inventive concept. Therefore, the disclosed preferred embodiments of the disclosure are used in a generic and descriptive sense only and not for purposes of limitation.

1. A semiconductor package comprising:
a first semiconductor die including a first surface and a second surface, which are opposite to each other in a vertical direction;
a second semiconductor die including a third surface and a fourth surface, which are opposite to each other in the vertical direction, the third surface facing the second surface of the first semiconductor die;
a first bonding layer in contact with the first surface of the first semiconductor die; and
a second bonding layer disposed between the second surface of the first semiconductor die and the third surface of the second semiconductor die, the second bonding layer being in contact with the second surface of the first semiconductor die,
wherein a width of the first bonding layer in a horizontal direction is smaller than a width of the second bonding layer in the horizontal direction, and
wherein the width of the second bonding layer in the horizontal direction is greater than a width of the first semiconductor die in the horizontal direction.

2. The semiconductor package of claim 1, wherein the width of the first bonding layer in the horizontal direction is the same as the width of the first semiconductor die in the horizontal direction.

3. The semiconductor package of claim 1, further comprising a filling film covering a sidewall of the first semiconductor die and being in contact with the second bonding layer.

4. The semiconductor package of claim 1, further comprising:
a third bonding layer being in contact with the third surface of the second semiconductor die and the second bonding layer; and
a fourth bonding layer being in contact with the fourth surface of the second semiconductor die,
wherein a width of the third bonding layer in the horizontal direction is different from a width of the fourth bonding layer in the horizontal direction.

5. The semiconductor package of claim 4, further comprising:
a first filling film covering a sidewall of the first semiconductor die and being in contact with the second bonding layer; and
a second filling film covering a sidewall of the second semiconductor die and being in contact with the third bonding layer.

6. The semiconductor package of claim 4, wherein the width of the third bonding layer in the horizontal direction is greater than the width of the fourth bonding layer in the horizontal direction.

7. The semiconductor package of claim 4, wherein the width of the third bonding layer in the horizontal direction is greater than the width of the second semiconductor die in the horizontal direction.

8. The semiconductor package of claim 7, wherein the width of the third bonding layer in the horizontal direction is the same as the width of the second bonding layer in the horizontal direction.

9. The semiconductor package of claim 4, wherein the width of the fourth bonding layer in the horizontal direction is the same as the width of the first bonding layer in the horizontal direction.

10. The semiconductor package of claim 4, wherein the width of the fourth bonding layer in the horizontal direction is the same as the width of the second semiconductor die in the horizontal direction.

11. A semiconductor package comprising:
a first semiconductor die including a first surface and a second surface, which are opposite to each other in a vertical direction;
a second semiconductor die including a third surface and a fourth surface, which are opposite to each other in the vertical direction, the third surface facing the second surface of the first semiconductor die;
a first bonding layer in contact with the first surface of the first semiconductor die; and
a second bonding layer disposed between the second surface of the first semiconductor die and the third surface of the second semiconductor die, the second bonding layer being in contact with the second surface of the first semiconductor die,
wherein a width of the first bonding layer in a horizontal direction is greater than a width of the second bonding layer in the horizontal direction, and
wherein the width of the second bonding layer in the horizontal direction is the same as a width of the first semiconductor die in the horizontal direction.

12. The semiconductor package of claim 11, further comprising:
a third bonding layer being in contact with the third surface of the second semiconductor die and the second bonding layer;
a fourth bonding layer being in contact with the fourth surface of the second semiconductor die;
a first bonding pad disposed on the first surface of the first semiconductor die, the first bonding pad passing through the first bonding layer;
a second bonding pad disposed on the second surface of the first semiconductor die, the second bonding pad passing through the second bonding layer;
a third bonding pad disposed on the third surface of the second semiconductor die, the third bonding pad passing through the third bonding layer; and
a fourth bonding pad disposed on the fourth surface of the second semiconductor die, the fourth bonding pad passing through the fourth bonding layer,
wherein the second bonding pad and the third bonding pad are in contact with each other.

13. The semiconductor package of claim 12, further comprising:
a first via disposed between the first bonding pad and the second bonding pad, the first via connecting the first bonding pad to the second bonding pad; and
a second via disposed between the third bonding pad and the fourth bonding pad, the second via connecting the third bonding pad to the fourth bonding pad.

14. The semiconductor package of claim 12, further comprising a filling film covering sidewalls of the first semiconductor die and the second semiconductor die, the filling film being in contact with the first bonding layer and the fourth bonding layer.

15. The semiconductor package of claim 11, further comprising:
a third bonding layer being in contact with the third surface of the second semiconductor die and the second bonding layer; and
a fourth bonding layer being in contact with the fourth surface of the second semiconductor die,
wherein a width of the third bonding layer in the horizontal direction is the same as the width of the second bonding layer in the horizontal direction.

16. The semiconductor package of claim 11, further comprising a third bonding layer that is in contact with the third surface of the second semiconductor die and the second bonding layer,
wherein the width of the first semiconductor die in the horizontal direction is the same as a width of the second semiconductor die in the horizontal direction, and
wherein the width of the second bonding layer in the horizontal direction is the same as a width of the third bonding layer in the horizontal direction.

17. The semiconductor package of claim 11, further comprising a third bonding layer being in contact with the third surface of the second semiconductor die and the second bonding layer,
wherein the width of the first semiconductor die in the horizontal direction is the same as a width of the second semiconductor die in the horizontal direction, and
wherein the width of the second semiconductor die in the horizontal direction is the same as a width of the third bonding layer in the horizontal direction.

18. The semiconductor package of claim 11, further comprising a third bonding layer being in contact with the third surface of the second semiconductor die and the second bonding layer,
wherein the width of the second bonding layer in the horizontal direction is the same as a width of the third bonding layer in the horizontal direction.

19. A semiconductor package comprising:
a base substrate;
a first semiconductor die disposed on the base substrate, the first semiconductor die including a first surface and a second surface, which are opposite to each other in a vertical direction;
a second semiconductor die having a third surface and a fourth surface, which are opposite to each other in the vertical direction, the third surface facing the second surface of the first semiconductor die;
a first bonding layer being in contact with the first surface of the first semiconductor die;
a second bonding layer disposed between the second surface of the first semiconductor die and the third surface of the second semiconductor die, the second bonding layer being in contact with the second surface of the first semiconductor die;
a third bonding layer being in contact with the third surface of the second semiconductor die and the second bonding layer;
a fourth bonding layer being in contact with the fourth surface of the second semiconductor die; and
a filling film covering sidewalls of the first semiconductor die and the second semiconductor die, the filling film being in contact with the first bonding layer and the fourth bonding layer,
wherein a width of the first bonding layer in a horizontal direction is greater than a width of the second bonding layer in the horizontal direction, and
wherein the width of the second bonding layer in the horizontal direction is the same as a width of the first semiconductor die in the horizontal direction.

20. The semiconductor package of claim 19, further comprising:
a first bonding pad disposed on the first surface of the first semiconductor die, the first bonding pad passing through the first bonding layer;
a second bonding pad disposed on the second surface of the first semiconductor die, the second bonding pad passing through the second bonding layer;
a third bonding pad disposed on the third surface of the second semiconductor die, the third bonding pad passing through the third bonding layer;
a fourth bonding pad disposed on the fourth surface of the second semiconductor die, the fourth bonding pad passing through the fourth bonding layer;
a first via disposed between the first bonding pad and the second bonding pad, the first via connecting the first bonding pad to the second bonding pad; and
a second via disposed between the third bonding pad and the fourth bonding pad, the second via connecting the third bonding pad to the fourth bonding pad.

21-28. (canceled)
